(19) United States
(12) Patent Application Publication
(10) Pub. No.: US 2004/0219711 A1
(43) Pub. Date: Nov. 4, 2004

(54) Method for manufacturing a polymer chip and an integrated mold for the same

(76) Inventors: Bi-Chu Wu, HsinChu (TW); Gin-Shu Young, HsinChu (TW)

Correspondence Address: Harold V. Stotland, Seyfarth Shaw, 42nd Floor, 55 East Monroe Street, Chicago, IL, 60603-5803, US

(21) Appl. No.: 10/427,347

(22) Filed: Apr. 30, 2003

(51) Int. Cl. H01L 21/44; H01L 21/48; H01L 21/50; H01L 23/02

(52) U.S. Cl. 438/106; 257/678

(57) ABSTRACT

The present invention discloses a method for manufacturing a polymer chip. The method first manufactures a plurality of unit mold, and each unit mold has a unit pattern corresponding to a pattern on the surface of the polymer chip for performing an operation. The unit molds are then selected and assembled to form an integrated mold according to a chip draft, and the unit pattern of the unit molds form an integrated pattern. The integrated mold is used in a molding process for manufacturing the polymer chip. The surface topography of the polymer chip is corresponding to the integrated pattern of the integrated mold, and can perform an integrated operation.

### BACKGROUND OF THE INVENTION

1. Field of the Invention

The present invention relates to a method for manufacturing a polymer chip and an integrated mold for the same, and more particularly, to a method for manufacturing a polymer chip using an integrated mold.

2. Background of the Invention

Recently, many research institutes have recognized that the development and application of the biochip technology combining microelectronics, micro-mechanics, life sciences and bio-information will cause a bio-technical revolution in the 21st century. FIG. 1 shows a flow chart for manufacturing a polymer microfluidic chip according to the prior art. The manufacturing processes for the polymer chip comprises five major steps, including chip design 10, mask manufacturing 12, semiconductor fabrication process 14, metallic mold manufacturing 16, and micro-molding of chip 18. The product from the semiconductor fabrication process 14 is a chip formed of silicon or polymer material. If a metallic mold with higher strength is required, the product from the semiconductor fabrication process 14 may be reproduced into a metallic mold, and the polymer chip can be manufactured by a micro-injection molding, thermal rolling, hot embossing or other duplication processes.

The semiconductor fabrication process 14 in FIG. 1 could be very complicated and may involve a large number of sub-processes. For example, FIG. 2 illustrates a semiconductor fabrication process for manufacturing a chip with two-step grooves according to the prior art. There are totally thirteen processes performed for manufacturing the chip with two-step grooves, including lithography, etching and deposition, etc.

The prior art technique for manufacturing the polymer chip possesses the following disadvantages:

1. The semiconductor fabrication process is expensive and time-consuming:

In the steps shown in FIG. 1, mask manufacturing 12 and semiconductor fabrication process 14 are the most time-consuming and expensive steps. Because these two steps use the professional techniques and equipments for the semiconductor fabrication, the manufacturing cost is rather expensive. If the manufacturing is outsourcing, the schedule will be difficult to control. Moreover, for a chip requiring small quantities and versatile types, the complicated semiconductor fabrication process will make the manufacturing cost for such small quantities and versatile types of chips even more expensive.

2. Lack of flexibility for changing the chip design

When there are design errors or impractical process in the manufacturing process of the chip and it is required to change the chip design, all the steps in FIG. 1 are necessary to be performed again, thus it is lack of flexibility for changing the chip design. Furthermore, since the mask cannot be modified partially, a new mask must be manufactured for a chip with partially different design, and all the mask manufacturing step 12, the semiconductor fabrication process step 14 and the metallic mold manufacturing step 16 need to be changed. Thus, the flexibility for changing chip design is quite poor.

3. Practical semiconductor fabrication techniques are not available for chips comprising a number of zones among which specification of one zone is dramatically different from another.

More and more functions and devices are integrated on a single chip, which means that the chip design and manufacturing have to satisfy the specification required by each function or device. Making an example of the Microfluidic chip, if a zone on the chip needs to have channels with large cross-sectional areas (ex. 500 μm×500 μm) while another zone may require channels with smaller ones (ex. 50 μm×50 μm), poor quality may result from the conventional semiconductor process since only one set of process parameters can be used for both zones. The parameters meeting the requirements for one zone may fail those for another zone.

Another example is when chips are produced with electroplating technique. The large difference in depth and width of the grooves on the same chip may generate a non-uniform surface. Further, the larger and thicker are the chip areas, the larger stress will be generated in the metal plating layers. Also, the interactive effect between processes performed on different zones of the chip will also make the manufacturing of chips more difficult. For example, one zone on the chip may require high temperature etching or deposition processes while another zone not needing the processes may suffer from them if extra protection is not provided. As the number of devices and functions integrated on the chip increases, the consideration by the interactive effect from various zones gets more complicated.

The U.S. patent publication NO. 2002/0124896 A1 discloses a modularized microfluidic system. The system comprises a plurality of modules for a single operation, and the modules are connected with a coupler to enable the fluid to flow from a module through the coupler to another module. In the disclosed publication couplers at the second level are needed to connect each individual module at the first level so that the fluid flow can be completed. For the microfluidic chip being miniaturized, additional steps for the design and manufacturing of the second floor couplers could be an issue. Besides, possibility of leakage at the coupler/module interfaces is another concern in such design. In addition, tremendous alignment and bonding efforts necessary for the two-level multi-element assembly is another issue to be considered.

Since the prior art techniques have the above-mentioned issues for the manufacturing time, cost and technical problems, an innovative method is required to response for the current and future technical requirements for polymer chips.

### SUMMARY OF THE INVENTION

The primary object of the present invention is to provide a method for manufacturing a polymer chip and an integrated mold for the same, which can reduce the manufacturing cost and time, increase the flexibility for changing chip design, and satisfy the current and future technical requirements for manufacturing the polymer chip.

To achieve the above-mentioned object, the present invention discloses a method for manufacturing a polymer chip and an integrated mold for the same. The method first manufactures a plurality of unit molds having at least a unit pattern, and the unit pattern is corresponding to a surface topography for the polymer chip for performing at least an operation. The unit molds are assembled to form an integrated mold, and the unit patterns forms an integrated pattern. A molding (duplication) process is performed to manufacture the polymer chip, the surface topography of the polymer chip is corresponding to the integrated pattern, and the surface topography can perform an integrated operation.

In case an even and continuous surface for the integrated mold after assembly needs to be ensured, a leveling off step can be performed to resolve the gaps or uneven surface levels between the neighboring unit molds before the duplication process. By pouring or coating some material in liquid form and curing it later on, the gaps and uneven surfaces between adjacent units molds are leveled off.

Compared with the prior art, the present invention uses an integrated mold to manufacture the polymer chip and the unit molds of the integrated mold are exchangeable, therefore the present invention has the following advantages:

1. Because different types of unit molds can be manufactured in mass production using the suitable processes to the specification, respectively, the manufacturing cost can be greatly reduced.

2. The unit molds corresponding to the patterns with large dimensional differences on the polymer chip can be made individually, so as to resolve the issue of interactive effect in the processing, and make the present invention compliant to the current and future technical requirement.

3. Because the unit molds can be selected and assembled according to the requirement of the chip for manufacturing the polymer chip, there is no need for waiting the time-consuming semiconductor process, and the manufacturing time for the polymer chip can be reduced.

4. Because each unit mold is exchangeable, for the situations of design errors or impractical processing, the mold can be re-assembled according to the modified design to manufacture the polymer chip, thus the present invention has high flexibility for the changing design.

### BRIEF DESCRIPTIONS OF THE DRAWINGS

FIG. 1 shows a flow chart for manufacturing a polymer chip according to the prior art;

FIG. 2 illustrates an example of semiconductor fabrication processes for a polymer chip according to the prior art;

FIG. 3 shows a flow chart for manufacturing the polymer chip according to the present invention;

FIG. 4 illustrates examples of unit molds according to the present invention;

FIG. 5 illustrates an example of design draft for the polymer chip according to the present invention;

FIG. 6 illustrates the unit molds for manufacturing the polymer chip according to the present invention;

FIG. 7 illustrates the integrated mold for manufacturing the polymer chip according to the present invention;

FIG. 8 illustrates one possible schematic process for manufacturing the polymer chip according to the present invention; and

FIG. 9 illustrates one possible schematic process to level off the integrated mold surface.

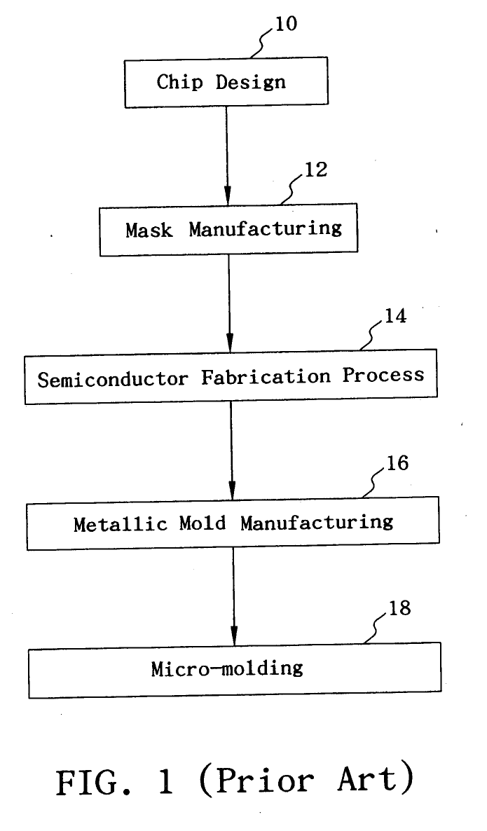

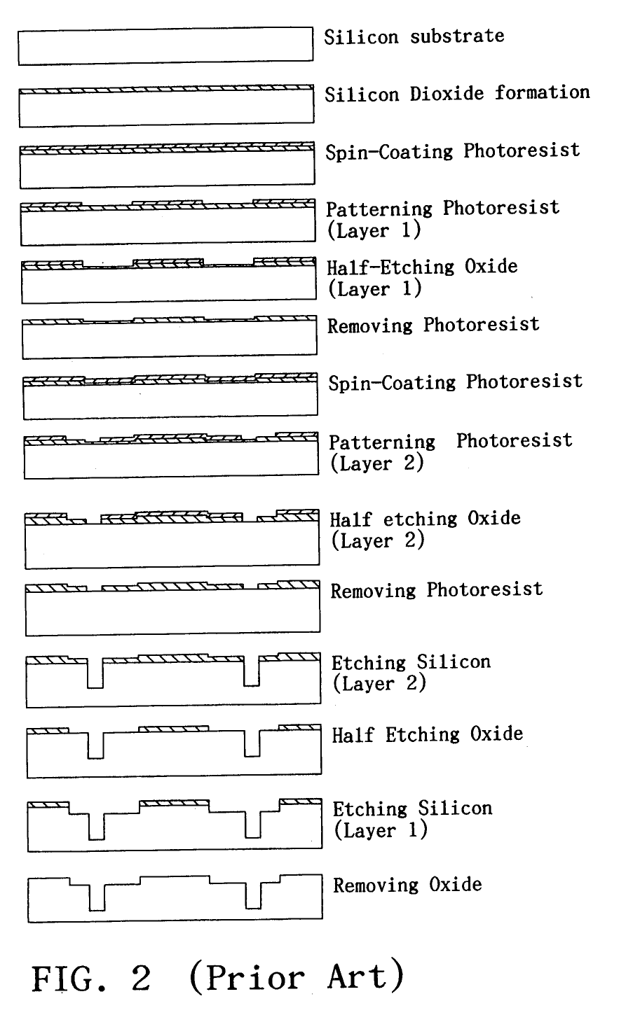

### DETAILED DESCRIPTION OF THE EMBODIMENTS

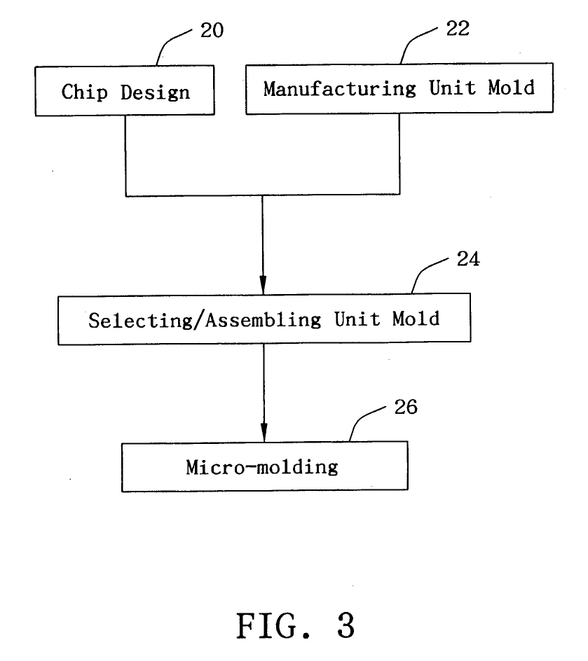

FIG. 3 shows a flow chart for manufacturing the polymer chip according to the present invention. As shown in FIG. 3, the present invention method for manufacturing the polymer chip mainly includes the chip design 20, manufacturing the unit molds 22, selecting/assembling the unit molds 24, and micro-molding of the polymer chips 26. The manufacturing of unit molds 22 can be performed in advance, for example, a series of commonly used unit molds such as channels, wells, mixers and T-shaped channels are manufactured in advance.

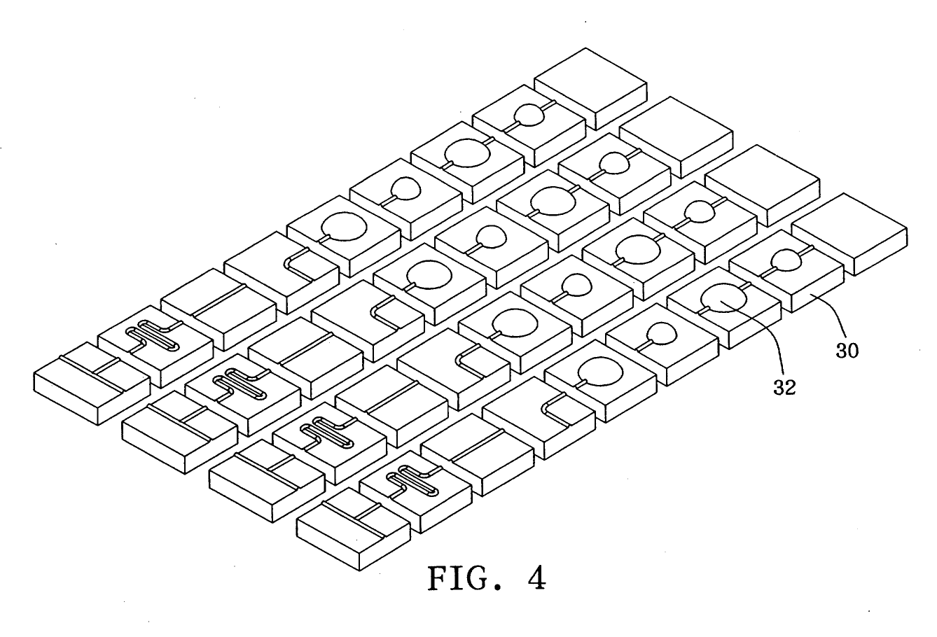

FIG. 4 illustrates a series of unit molds 30. The present invention analyzed the characteristics of the polymer chip, divided it into several classifications, and manufactured the unit molds 30. As shown in FIG. 4, the unit pattern 32 for the unit mold 30 may be a strip, a circle, or any other simple or complicated shapes. The patterns of the unit mold 30 with different sizes can be manufactured according to the design rule of the chips. The surface topography of the unit pattern 32 defines a single operation or multiple operations of a chip. For example, the strip patterns with different sizes defines a straight channel, a curved channel, a T-shaped junction, or a continuous curved channel for performing a mixing operation, and the circle patterns with different radiuses are used to define the wells for storing fluids. A unit mold can also comprise a plurality of wells, channels, junctions, or other shapes linked in serial or in parallel to perform a more complicated function such as separation, mixing, valving, or pumping within the unit mold.

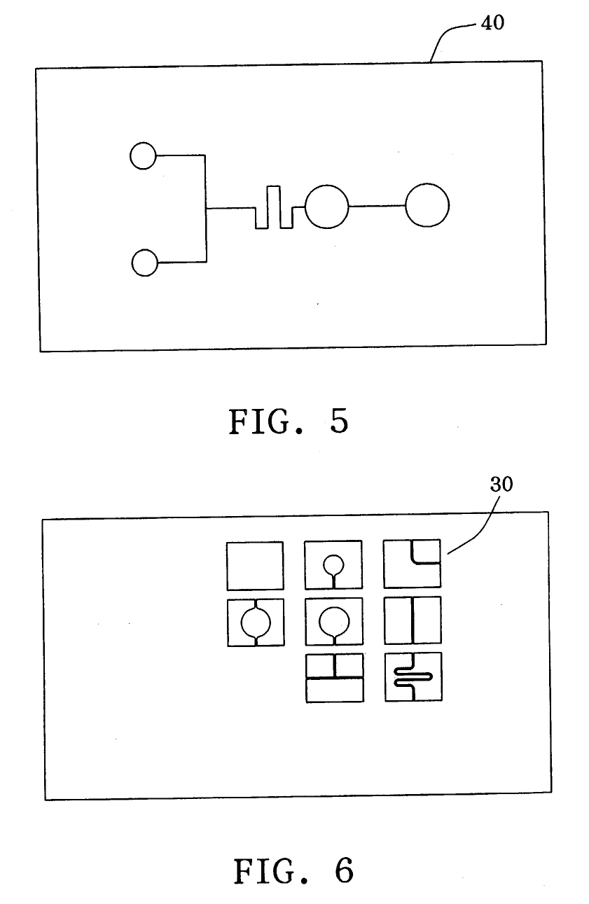

FIG. 5 illustrates an example of a polymer microfluidic chip design draft 40. Once the design draft of the polymer chip 40 is completed, one can analyze the detailed functions of the polymer chip 40, classify these functions, and select necessary unit molds 30. The unit mold 30 can be made of silicon, metal or other materials.

FIG. 6 illustrates the necessary unit molds 30 for manufacturing the polymer chip 40. As shown in FIG. 6, there are eight types of unit mold 30 necessary for manufacturing the polymer chip 40, and totally fifteen unit molds are necessary. After the selection of unit molds 30, the unit molds 30 are assembled to form an integrated mold 50 according to the design draft of the polymer chip 40.

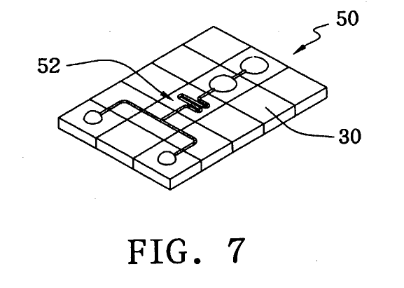

FIG. 7 illustrates the integrated mold 50 for manufacturing the polymer chip 40 according to the present invention. As shown in FIG. 7, the integrated mold 50 comprises fifteen unit molds 30, and the unit patterns 32 of these fifteen unit molds 30 form an integrated pattern 52. Because the integrated mold 50 is composed of the unit molds 30 according to the present invention, it only needs to replace the unit molds 30 to manufacture a polymer chip with specific functions within a very short period (preferably within one hour).

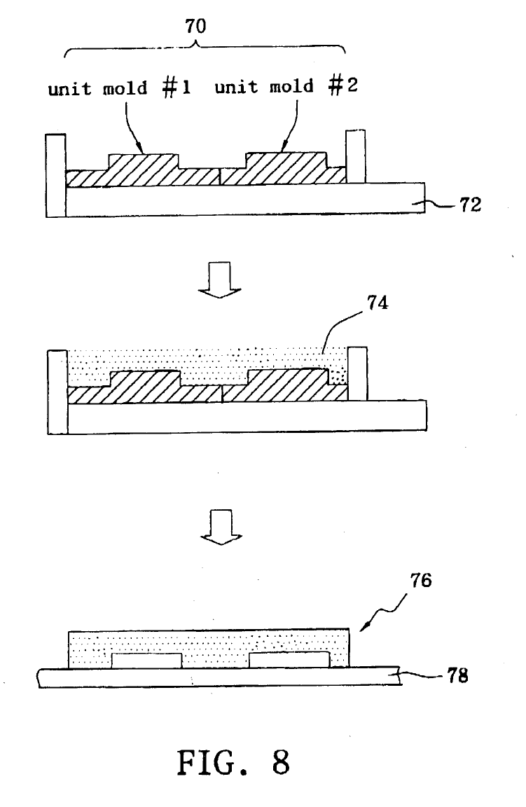

Once an integrated mold is assembled, conventional polymer replication techniques such as injection molding, hot embossing, casting or other methods can be used to manufacturing polymer chips. FIG. 8 illustrates one possible schematic process for manufacturing the polymer chip according to the present invention. As shown in FIG. 8, polymer material 74 in a plastic state is poured into the fixture 72 clamping the integrated mold 70. Heating or UV process is followed to cure the polymer in fixture. Once cured, the polymer chip 76 can then be removed from the fixture 72 and bonded to a proper substrate 78 for further application. The polymer can be Polydimethylsiloxane, Polycarbonate Polyacrylate or other material.

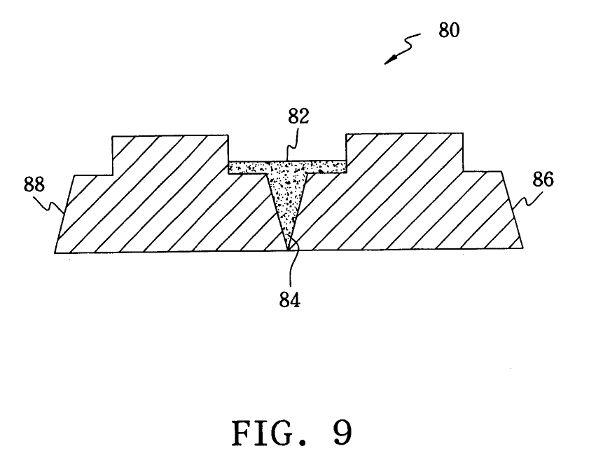

In case an even and smooth surface on the integrated mold is required after unit mold assembly, a leveling off step can be performed before the replication step to solve the gaps or uneven surface levels between the adjacent unit molds. As illustrated in FIG. 9, by pouring or coating a material 82 in liquid form onto the integrated mold 80 and the material 80 is then cured into solid. The gap 84 between the two unit molds 86 and 88 is filled with the solidified material 80 and the uneven surface of the adjacent unit molds are leveled off.

The integrated patterns 52 of the integrated mold can be either convex or concave. When it is convex, the surface topography of the polymer chip 40 is concave so that the surface topography for the polymer chip 40 is corresponding to the integrated patterns 52 of the integrated mold 50. Moreover, the integrated mold 50 of the present invention can also be used in a reproducing process for manufacturing a mold with special characteristics such as a mold with higher strength. The mold from the integrated mold 50 can be used to manufacture the polymer chip, and the surface topography for the completed polymer chip is still corresponding to the integrated pattern 52 of the integrated mold 50. Compared with the prior art, the present invention uses an integrated mold to manufacture the polymer chip and the unit molds of the integrated mold are exchangeable, therefore the present invention has the following advantages:

1. Because different types of unit molds can be manufactured in mass production using the suitable processes to the specification, respectively, the manufacturing cost can be greatly reduced.

2. The unit molds corresponding to the patterns with large dimensional differences on the polymer chip can be made individually, so as to resolve the issue of interactive effect in the processing, and make the present invention compliant to the current and future technical requirement.

3. Because the unit molds can be selected and assembled according to the requirement of the chip to assemble the integrated mode for manufacturing the polymer chip, there is no need for waiting the time-consuming semiconductor process, and the manufacturing time for the polymer chip can be reduced.

4. Because each unit mold is exchangeable, for the situations of design errors or impractical processing, the mold can be re-assembled according to the modified design to manufacture the polymer chip, thus the present invention has high flexibility for the changing design.

The above-described embodiments of the present invention are intended to be illustrative only. Numerous alternative embodiments may be devised by those skilled in the art without departing from the scope of

What is claimed is:

1. A method for manufacturing a polymer chip, comprising the steps of:
manufacturing a plurality of unit molds, wherein each unit mold has at least one unit pattern for defining a part of a surface topography of the polymer chip;
assembling the plurality of unit molds to form an integrated mold with an integrated pattern assembled by the unit patterns, wherein the integrated pattern corresponds to the surface topography of the polymer chip; and
performing a molding process by the integrated mold for manufacturing the polymer chip.

2. The method for manufacturing a polymer chip of claim 1, wherein the molding process is an injection molding, a hot embossing, a casting or a pour and cure process.

3. The method for manufacturing a polymer chip of claim 1, wherein the polymer is plastic Polydimethylsiloxane.

4. The method for manufacturing a polymer chip of claim 1, wherein the polymer is plastic Polycarbonate or Polyacrylate.

5. The method for manufacturing a polymer chip of claim 1, wherein the function of the polymer chip can be changed by replacing the unit mold.

6. The method for manufacturing a polymer chip of claim 1, wherein the unit pattern is shaped like a circle for defining a well of the polymer chip.

7. The method for manufacturing a polymer chip of claim 1, wherein the unit pattern is shaped like a strip for defining a channel, a curved channel and a continues curved channel of the polymer chip.

8. The method for manufacturing a polymer chip of claim 1, further comprising at least a reproducing process.

9. The method for manufacturing a polymer chip of claim 1, wherein the unit pattern comprises a plurality of linked shapes so that a unique microfluidic function can be completed within the unit pattern, and the unique microfluidic function can be separation, mixing, valving or pumping.

10. The method for manufacturing a polymer chip of claim 1, further comprising a leveling off step, wherein the leveling off step comprising:
forming a liquid material onto the surface of the integrated mold; and
Solidifying the liquid material.

11. An integrated mold for manufacturing a polymer chip, comprising a plurality of unit molds, each unit mold having at least one unit pattern for defining a part of a surface topography of the polymer chip and performing at least one operation.

12. The integrated mold for manufacturing a polymer chip of claim 11, wherein the unit mold can be replaced to change the function of the polymer chip.

13. The integrated mold for manufacturing a polymer chip of claim 11, wherein the unit pattern is T-shaped.

14. The integrated mold for manufacturing a polymer chip of claim 11, wherein the unit pattern is shaped like a strip for defining a channel of the polymer chip.

15. The integrated mold for manufacturing a polymer chip of claim 11, wherein the unit pattern is shaped like a circle for defining a well of the polymer chip.

16. The integrated mold for manufacturing a polymer chip of claim 11, wherein the unit mold is made of silicon or metal.

17. The integrated mold for manufacturing a polymer chip of claim 11, wherein the polymer chip is a microfludic chip.

18. The integrated mold for manufacturing a polymer chip of claim 11, wherein the unit mold comprises a plurality of linked shapes so that a unique microfluidic function can be completed within the unit pattern, and the unique microfluidic function can be separation, mixing, valving or pumping.
